(19) United States
(12) Patent Application Publication
(10) Pub. No.: US 2026/0328830 A1
(43) Pub. Date: Oct. 22, 2026

(54) Cable Condition Monitoring using Inductive Approach

(71) Applicant: Battelle Memorial Institute, Richland, WA (US)

(72) Inventors: Samuel W. GLASS, III, Greensboro, NC (US); Jonathan R. TEDESCHI, Richland, WA (US); Leonard S. FIFIELD, Richland, WA (US)

(21) Appl. No.: 19/252,131

(22) Filed: Jun. 27, 2025

Related U.S. Application Data
(60) Provisional application No. 63/665,873, filed on Jun. 28, 2024.

(51) Int. Cl. G01R 31/11

(52) U.S. Cl. CPC G01R 31/11

(57) ABSTRACT

Conductive structures such as electrical cables are subject to mechanical damage, electrical overstress, thermal, radiation, moisture, or other factors that can degrade or destroy performance. Cable performance can be impacted not only by damage to a conductive structure, but also by damage or environmental degradation of dielectric materials such as those between conductors or forming a jacket of the cable. A cable monitoring approach can use a reflectometric measurement technique involving inductively-coupled excitation or inductive detection, or both. Use of inductive coupling can simplify test procedures, allowing a non-invasive cable test scheme that can be used either intermittently for discrete inspection tasks, or for more frequent (or even continuous) cable monitoring in situ during energized operation. Such an approach does not require a conductive connection between the inspection apparatus and the cable under test.

### CLAIM OF PRIORITY

This patent application claims the benefit of priority of Glass, et al., U.S. Provisional Patent Application No. 63/665,873, titled “CLAMSHELL INDUCTIVE CURRENT COUPLER FOR ONLINE CABLE CONDITION MONITORING AND METHODS FOR USING,” filed on Jun. 28, 2024 (Client Ref. 33011-E PROV), which is hereby incorporated by reference herein in its entirety.

### STATEMENT REGARDING FEDERALLY SPONSORED RESEARCH OR DEVELOPMENT

This invention was made with Government support under Contract DE-AC0576RL01830 awarded by the U.S. Department of Energy. The Government has certain rights in the invention.

### FIELD OF THE DISCLOSURE

This document pertains generally, but not by way of limitation, to apparatus and techniques for cable condition monitoring, such as for single-conductor or multi-conductor power cable monitoring, and more particularly, to an inductive coupling approach that does not require the cable under inspection to be disconnected or de-energized, which can include or use a frequency domain reflectometry (FDR) approach or spread-spectrum time domain reflectometry (SSTDR) approach, or other test approaches.

### BACKGROUND

Conductive structures such as electrical cables are subject to mechanical damage, electrical overstress, thermal, radiation, moisture, or other factors that can degrade or destroy performance. Users of such cables may implement test or monitoring programs to verify function or otherwise to help assure that the cables can operate safely and reliably, particularly in safety-critical applications. Cable performance can be impacted not only by damage to a conductor, but also by damage or environmental degradation of dielectric materials such as those between conductors or forming a jacket of the cable.

In one approach, a cable under inspection is de-energized and disconnected from a source and a load device (e.g., motor, actuator, or sensor) to perform measurements which involve connecting test instrumentation conductively (e.g., physically in galvanic contact) to one or more conductors of the cable. Measurements can then be obtained by conductively injecting a signal into the cable and conductively measuring a resulting response. Such an approach can present various challenges, such as imposing costs and risks associated with de-energizing and disconnecting the cable under inspection.

For example, inspection may involve skilled personnel manually de-energizing the cable, disconnecting the cable under inspection and connecting it to test instrumentation, and then, assuming no anomalies are detected, reconnecting and restoring the cable to service. Such an approach can be susceptible to error or may even induce failure due to cycling of interconnections or mechanical damage, reducing uptime or compromising reliability. Such an approach may also be inconvenient or even impractical, precluding continuous monitoring or frequent inspection.

### SUMMARY OF THE DISCLOSURE

The present inventors have recognized, among other things, that cable monitoring can benefit from an approach that does not require the cable under test to be de-energized during inspection or disconnected for inspection. The present inventors have also recognized that, among other things, a cable monitoring approach can use inductively-coupled excitation or inductive detection, or both. Use of inductive coupling can simplify test procedures, allowing a non-invasive cable test scheme that can be used either intermittently for discrete inspection tasks, or for more frequent (or even continuous) cable monitoring in situ during energized operation. Such an approach does not require a conductive connection between the inspection apparatus and the cable under test, though the test apparatus may be referenced to an electrical potential that is also connected to one or more cable conductors (e.g., a chassis or “ground” reference or equipment grounding conductor for safety).

Use of an inductive coupling approach for cable inspection can also provide line voltage isolation, providing an isolation barrier between test instrumentation and an energized live conductor under inspection. For example, the present subject matter can include use of test signals having a voltage magnitude in the range of ones or tens of volts, while a conductor structure under test can be energized to hundreds, thousands, or even tens of thousands of volts, relative to the test signals, as illustrative examples.

In an example, a system for reflectometric evaluation of a cable comprises comprising an excitation circuit configured to generate an excitation signal for inductive application to a conductive structure of a cable for spread-spectrum time domain reflectometry (SSTDR) or frequency domain reflectometry (FDR), a measurement circuit configured to receive a reflected signal obtained inductively from the conductive structure of the cable, the reflected signal for use in determining an indicium of a feature along the cable using the spread-spectrum time domain reflectometry (SSTDR) or the frequency domain reflectometry (FDR), and at least one inductive current probe defining an opening to encircle an outer diameter of the cable, the inductive current probe configured to at least one of inductively apply the excitation signal or inductively receive the reflected signal, or both inductively applying the excitation signal and inductively receiving the reflected signal. In an example, the system includes that the at least one inductive current probe comprises a clamp-on configuration defining an opened configuration and a closed configuration, the open configuration allowing the inductive current probe to be applied to or removed from the cable. In an example, the system includes that the at least one inductive current probe comprises a dielectric spacer located on or within an opening of the inductive current probe, the dielectric spacer sized and shaped to center the cable within the opening. In an example, the at least one inductive current probe comprises two or more inductive current probes for positioning at different locations along the cable, respectively.

In an example, a method (such as a machine-implemented method) for reflectometric evaluation of a cable comprises generating an excitation signal for inductive application to a conductive structure of a cable for spread-spectrum time domain reflectometry (SSTDR) or frequency domain reflectometry (FDR). In response to the excitation signal, the method includes receiving a reflected signal obtained inductively from the conductive structure of the cable, the reflected signal for use in determining an indicium of a feature along the cable using the spread-spectrum time domain reflectometry (SSTDR) or the frequency domain reflectometry (FDR), where at least one of the inductive application or the receiving the reflected signal is performed, or both are performed, using at least one inductive current probe defining an opening to encircle an outer diameter of the cable. In an example, a machine-readable medium comprises instructions that, when executed by a reflectometric measurement system, perform the method.

This summary is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example comprising a system that can be used for reflectometric evaluation of a cable.

FIG. 2A illustrates generally an example comprising an inductive current probe, such as can be included or used with other examples.

FIG. 2B-1 and FIG. 2B-2 illustrate generally an example showing a coupler and spacer combination comprising an inductive current probe that is fitted with a two-part dielectric spacer assembly.

FIG. 2C-1 and FIG. 2C-2 illustrate generally examples comprising an exploded view of an inductive current probe and two different dielectric spacer arrangements.

FIG. 2D illustrates generally an example comprising a test setup, such as where an inductive current probe and a dielectric spacer arrangement are used to position (e.g., center) a cable under test within an opening defined by the inductive current probe.

FIG. 3A shows an illustrative example of insertion loss versus frequency from vendor-provided data, for a representative inductive current probe that can be used for inductive coupling of an excitation signal to a cable under test, or detection of a received signal elicited by such excitation.

FIG. 3B shows an illustrative example comprising experimentally-obtained insertion loss values measured versus frequency, showing rejection of power line frequencies and lower order harmonics.

FIG. 4 illustrates generally an example comprising an instrument architecture for a frequency domain reflectometer (FDR) instrument, such as can be included or used with other examples.

FIG. 5 illustrates generally an example comprising an instrument architecture for a spread-spectrum time domain reflectometer (SSTDR) instrument, such as can be included or used with other examples.

FIG. 6 illustrates generally an example comprising a test configuration showing differences between hypothetical reflectometry measurements for connected (e.g., energized) and disconnected cable configurations, for inductively-coupled and conductively coupled measurements.

FIG. 7A shows an illustrative example comprising experimentally-obtained normalized magnitude values obtained using a frequency domain reflectometry (FDR) approach using a direct connection and de-energized cable under test, and FIG. 7B shows a composite fault profile after baseline removal and aggregation (e.g., multiplication) of the signals in FIG. 7A to combine them into a composite fault profile.

FIG. 8A shows an illustrative example comprising experimentally-obtained normalized magnitude values obtained using a frequency domain reflectometry (FDR) approach using an inductively-coupled connection and 480 VAC energized cable under test, and FIG. 8B shows a composite fault profile after baseline removal and aggregation (e.g., multiplication) of the signals in FIG. 8A to combine them into a composite fault profile.

FIG. 9 shows an illustrative example comprising experimentally-obtained normalized magnitude values obtained using a frequency domain reflectometry (FDR) approach using an inductively-coupled clamped on probe that interrogates a medium voltage shielded cable.

FIG. 10A illustrates generally a technique, such as a machine-implemented method that can include or use an inductive coupling approach for performing a reflectometric measurement using, for example, a single coupler.

FIG. 10B illustrates generally another technique, such as a machine-implemented method that can include or use an inductive coupling approach for performing a reflectometric measurement using multiple couplers.

FIG. 11A, FIG. 11B, FIG. 11C, FIG. 11D, and FIG. 11E illustrate generally operations that can include or use two or more inductive coupling probes to perform a reflectometric technique, such as a machine-implemented method.

FIG. 12 illustrates a block diagram of an example comprising a machine upon which any one or more of the techniques (e.g., methodologies) discussed herein may be performed.

### DETAILED DESCRIPTION

The present subject matter can include or use an inductive coupling approach to perform reflectometric testing. For example, such testing can include or use a frequency domain reflectometry (FDR) approach or spread-spectrum time domain reflectometry (SSTDR) approach to evaluate a cable. Such measurements can, for example, evaluate cable insulation degradation or other anomalies. The cable under inspection need not be disconnected or even de-energized during inspection.

As an illustration, safety-critical nuclear power plant cables may generally be qualified for a 40-year operational lifespan. However, as plants extend their operating licenses to 60 years, 80 years, or beyond 80 years, justification for continued safe operation may involve implementation and execution of ongoing test and monitoring programs. As mentioned above, in one approach manual intervention is used to perform such monitoring, including disconnecting the cables, performing one or several tests, then reconnecting the cables. This manual intervention may be limited to being performed in conjunction with refueling outages occurring every couple of years, otherwise forcing downtime. This intermittent and labor-intensive approach can pose an operational burden. The present subject matter can help to address such burden, such as by facilitating “online” testing that can be performed without requiring disconnection or even without requiring de-energizing the cable under inspection.

Cable degradation can occur due to a number of factors including heat, moisture, chemical exposure, radiation, flexure, abrasion, or pinching, as illustrative but non-limiting examples. Such factors can lead to cable insulation materials crumbling, separating, or eroding, such as degrading dielectric insulation properties, or even being breached and exposing conductors. Different faults may exhibit low-resistance, short, or open circuit conditions with corresponding circuit failures, operational outages, or safety concerns. Cable monitoring approaches can help to detect early indications of an incipient fault or degradation before system failure, and such monitoring approaches can be used to localize areas of interest to guide supplemental inspections or damage management. One such approach is electrical reflectometry. Radio frequency (RF) reflectometry techniques generally involve generation and detection of high-frequency signals over a broad frequency range (such as selected from a range extending from kHz to hundreds of MHz). The use of the phrase “radio frequency” does not exclude microwave frequencies and can generally refer to frequencies beyond line frequency and lower order harmonics of line frequency up to and including microwave frequencies of around 1 GHz or more.

In general, an output from a reflectometric measurement technique is a plot (or corresponding data) representing a value, such as a normalized reflected signal magnitude versus time or versus a distance from the receiver (e.g., when a propagation velocity is known). Indications or features such as magnitude peaks in the plot generally correspond to physical loci along the cable where impedance discontinuities are present. Such indicia in the reflectometric data can include features corresponding to regions of the cable under inspection comprising thermal damage, mechanical damage, an insulation defect, or a conductor defect, or combinations thereof. Although no single test protocol can assure detection of all damage mechanisms, inductively-coupled high-frequency reflectometry approaches as shown and described herein can be applied without affecting low-frequency or direct current (DC) power applications and can not only detect but also help to locate (e.g., localize) indications of concern.

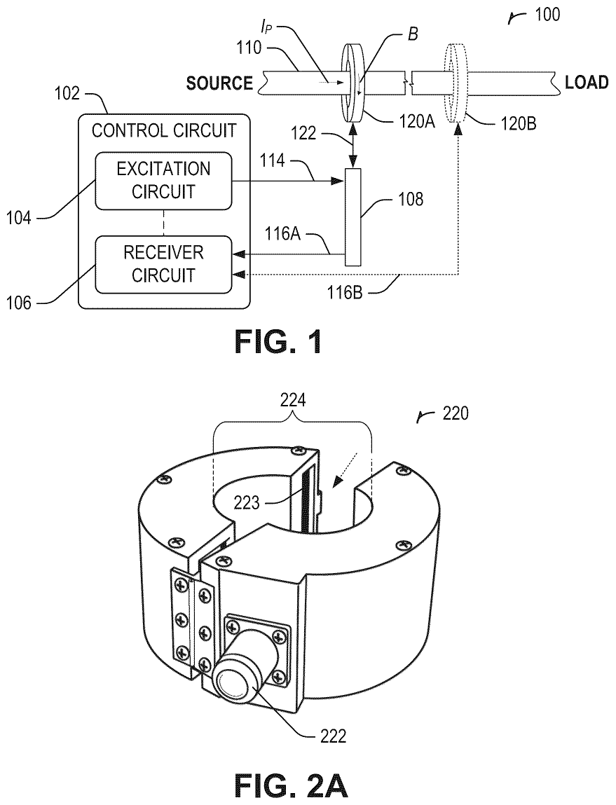

FIG. 1 illustrates generally an example comprising a system 100 that can be used for reflectometric evaluation of a cable 110. As shown and described below, the cable 110 can include a single conductor or multiple conductors and can be shielded or unshielded. A current, Ip, flowing through the cable 110 induces a corresponding magnetic flux density, B, in a ferrite or ferromagnetic core of the inductive current probe 120A encircling a region of the cable 110. Various inductive current probe configurations exist, with one example being a current transformer configuration. In a current transformer configuration, a readout conductor can be wrapped around (e.g., “linked”) a core to measure a secondary current, Is, that is proportional to a count of turns wrapped around the core, in relation to the primary current. Through a principle of reciprocity, the inductive current probe 120A can also be used to inject a current into the cable 110. For example, in the current transformer configuration, excitation of the secondary (e.g., readout) winding of the current transformer can induce a magnetic flux density, B, which then results in current, Ip, being non-conductively injected into the cable 110.

As shown and described herein, a test instrument 102, such as a frequency domain reflectometer (FDR) or spread-spectrum time-domain reflectometer (SSTDR) can include an excitation circuit 104 having an output 114 that can drive the inductive current probe 120A, and a receiver circuit 106 having an input 116A that can receive a signal from the inductive current probe 120A. In this manner, a frequency domain chirp or pseudo-noise modulated time-domain pulse can be injected into the cable 110 and corresponding reflections associated with impedance discontinuities can be detected, such as logged and analyzed. Coupling of the output 114 or input 116A can be accomplished through a directional coupler, multiplexer, or transmit/receive switch arrangement 108, such as to provide signals to or from a port 122 (e.g., a coaxial port) of the inductive current probe 120A.

The inductive current probe 120A shown illustratively in FIG. 1 can include a single coil that may be used for either or both current injection or readout, or, as another example, a single coupler body can be used that includes separate windings, such as a pair of windings, with one configured for transmission of signals and one configured to reception of reflected signals. In such a multi-winding configuration, each respective winding can be electrically fed or monitored using its own electrical port (e.g., a respective coaxial connector or other configuration).

The use of a single inductive current probe 120A assembly is merely illustrative, and other configurations are possible. For example, the inductive current probe 120A can be a first one amongst two or more such inductive current probes located at different positions along the cable. The inductive current probe 120A may be positioned a first location along the cable 110, and a second inductive current probe 120B can be positioned at a different second location along the cable 110. The test instrument 102 can include multiple receive channels, such as a second input 116B to receive reflections at a different second location along the cable 110. In yet another example, the second inductive current probe 120B (or other probes) can be driven with its own excitation to make independent reflectometric measurements at the different second location. For example, measurements from a second location can be used for localization of detected features along the cable 110, or for determination that an indication be disregarded, such as associated with a source or an end termination that is not of interest. As with single coupler examples, a multi-coupler example may include or use individual couplers that respectively include single coils used for both reception and transmission or that include multiple coils with each configured to perform either reception or transmission.

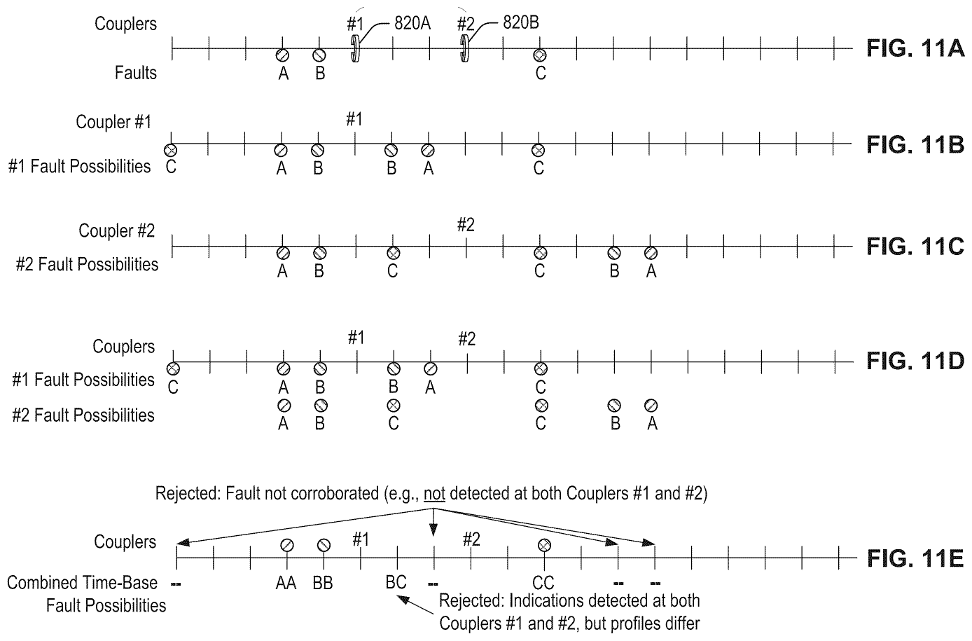

Depending on the inspection configuration (e.g., whether the source or load devices remain connected during testing), ambiguity may exist with respect to a physical location of a fault indication, when only a single probe is used. In general, excitation of the cable 110 causes propagating excitation pulses to be launched in opposing directions, due to transmission line behavior of the cable 110. Techniques for resolving such ambiguity are discussed elsewhere below, such as in relation to the operations described in FIG. 11A, FIG. 11B, FIG. 11C, FIG. 11D, and FIG. 11E.

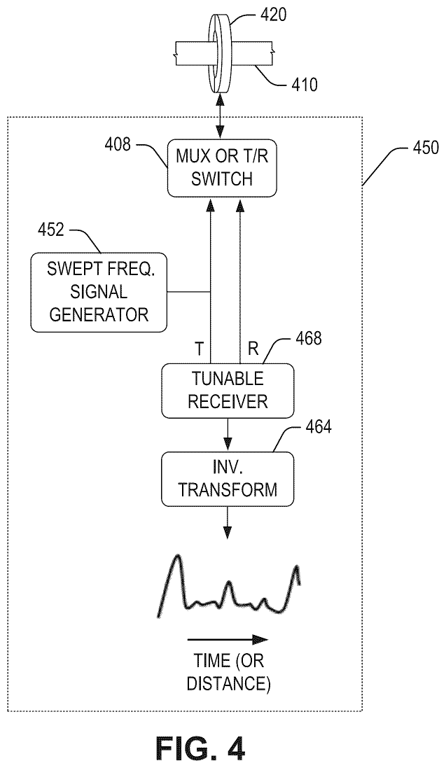

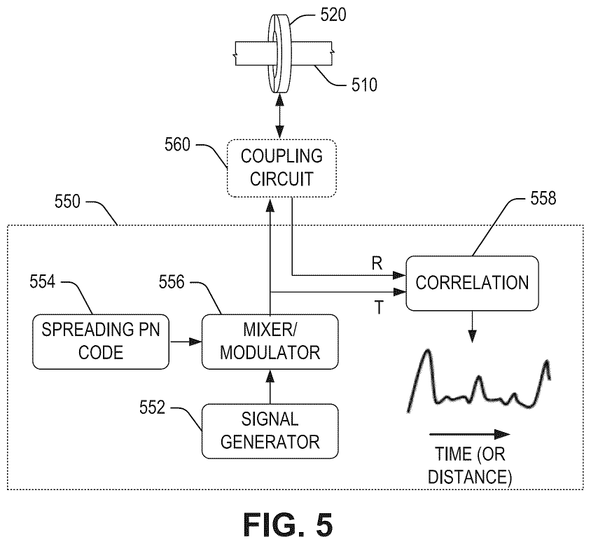

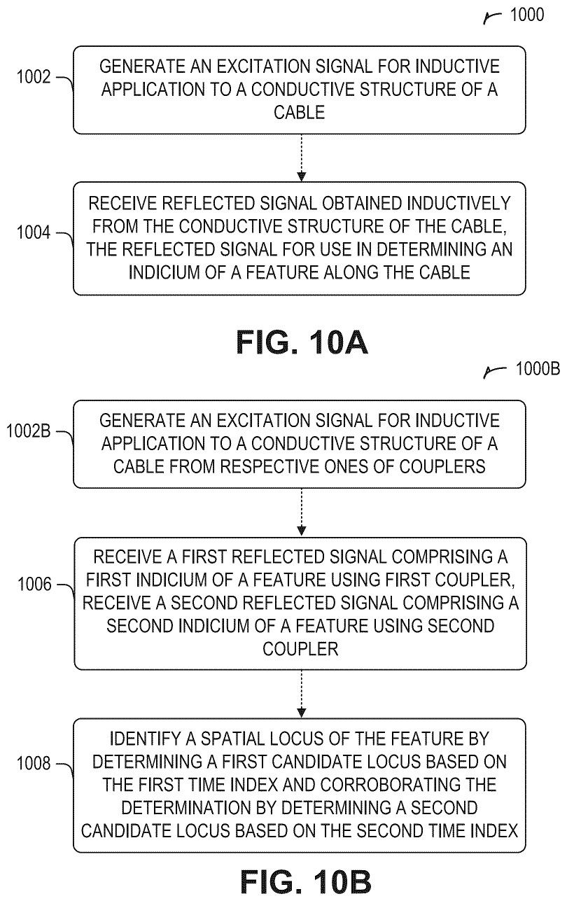

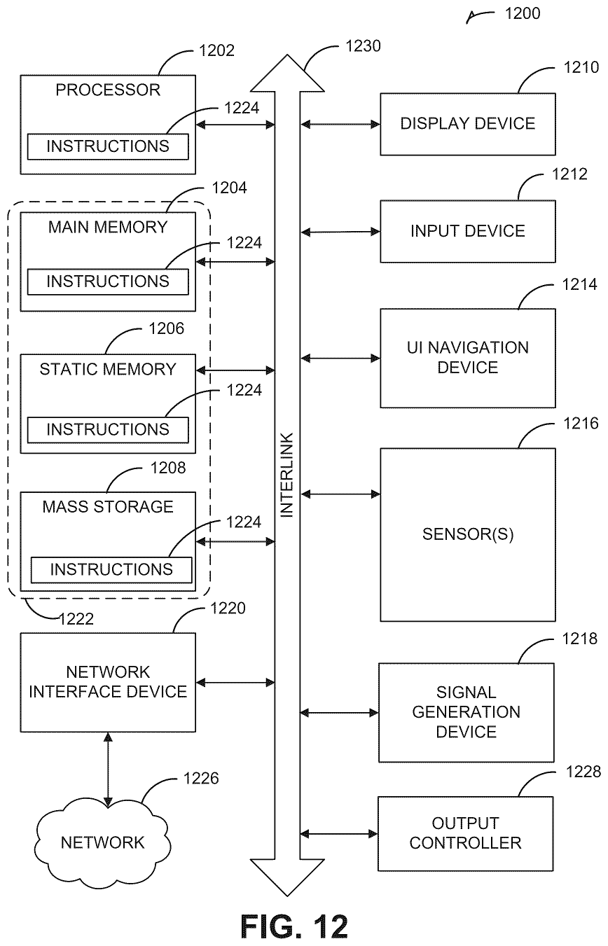

The test instrument 102 can implement an architecture of an FDR or SSTDR as shown in FIG. 4 or FIG. 5 and can include some or all features shown in the illustrative example of FIG. 12, forming an embedded measurement system that can execute instructions corresponding to one or more techniques described in this document, such as the technique shown in FIG. 10A, FIG. 10B, or the operations described in FIG. 11A, FIG. 11B, FIG. 11C, FIG. 11D, and FIG. 11E.

In general, SSTDR or FDR instrumentation (e.g., a vector-network analyzer or VNA-based FDR) have excitation output level and receiver input level limitations. Most instruments are limited to no more than tens of volts, or even lower input signal magnitudes, at 60 Hz to avoid damage. Without a protection or isolation circuit, high-voltage DC or 60 Hz alternating current (AC) line voltage (which can range from 120 V RMS to more than 15 kV RMS in industrial settings) may damage such equipment. One approach to perform conductive measurements is to use a high-pass filter that can suppress DC and 60 Hz low-frequency line voltage signals and allow higher frequencies to pass through. This, however, is generally not practical to support both high-voltage suppression and passing of high frequencies (e.g., greater than 100 MHz). Therefore, instead of a discrete filter or isolator, an inductive current probe having a frequency-dependent transfer impedance can be used to provide such isolation and filtering.

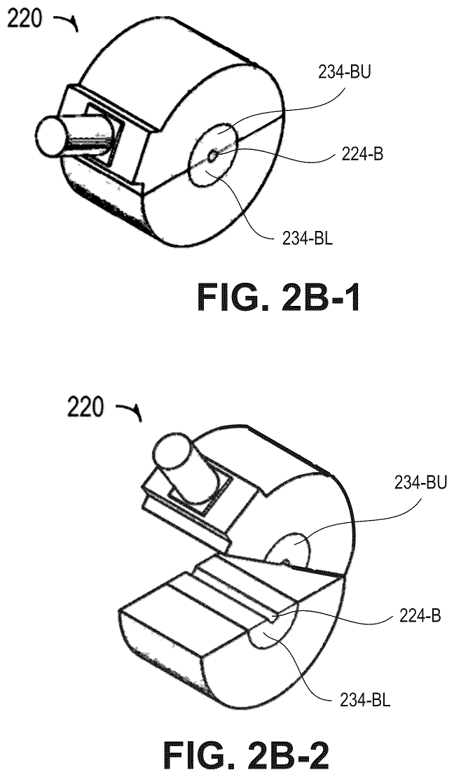

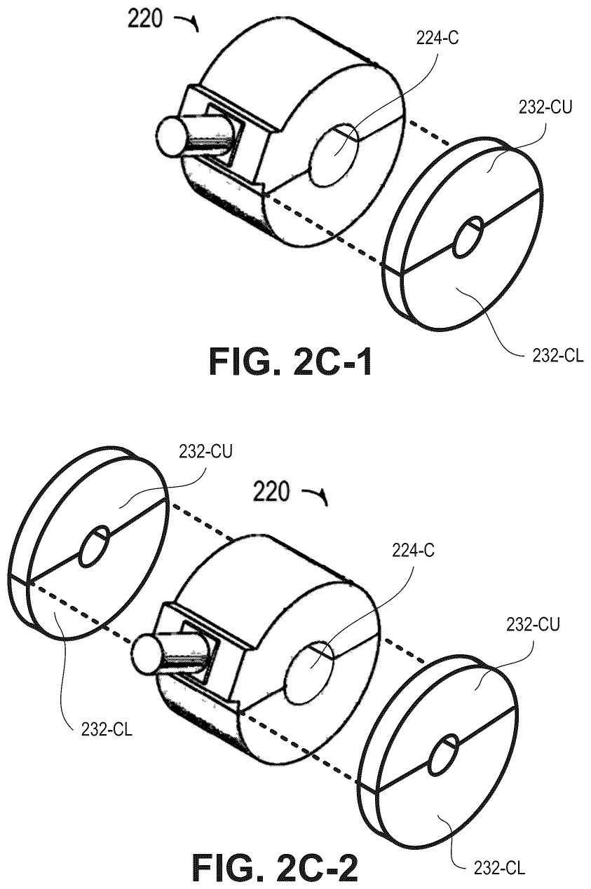

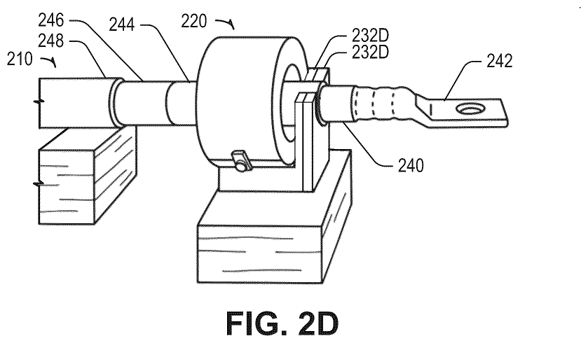

FIG. 2A illustrates generally an example comprising an inductive current probe 220, such as can be included or used with other examples. As mentioned above, an inductive coupler can be used to inject a signal (such as driven at a coaxial port 222) into a cable conductor and the same coupler or another coupler can be used to listen for a reflected signal, such as indicative of damage. As described in various examples herein, generally-available inductive current probe configurations can provide greater than 60 dB of attenuation at line frequencies, facilitating tests on energized cables operating at tens of kilovolts (kV) or greater voltages. Use of an inductive current probe 220 can provide both rejection of unwanted line frequency energy at the front-end of the receiver, and line voltage isolation.

The illustrative example of FIG. 2A shows a generally-available current probe 220 that has the ability to both transmit and receive and can be used to inject and sense RF signals on a live cable while providing low-frequency isolation to protect RF test equipment. As an illustrative example, the probe 220 shown in FIG. 2A corresponds to an ICP-622 injection current probe (available from A.H. Systems, Inc, Chatsworth, California). An opening 224 is defined in the center of the probe, and a clamp-on or “clamshell” configuration allows semi-circular regions of the inductive current probe 220 to be separated (providing an opened configuration as shown in FIG. 2A) creating an opening through which a cable or other conductive structure can be passed without requiring the cable to be disconnected in order to place it within the opening 224. This configuration is superficially similar to clamp-on probe arrangements used for passive current measurement such as included or used with volt-ohm meters for monitoring AC line current in a single conductor, but the configuration shown in FIG. 2A having a ferrite core 223 may usable up to microwave frequencies and can be used for both injection and detection, unlike low-voltage and low-frequency clamp-on hall-effect-based or Rogowski current probes used for AC line current measurement.

In general, a count of windings influences a characteristic impendence of the probe 220 and sets the current at which the core 223 (e.g., a ferrite material) will saturate, with other parameters such as parasitic capacitance between secondary windings established to achieve acceptable performance for high-frequency operation. RF current probes configured as current transformers generally measure, or produce, a voltage across a specified termination load (e.g., a 50-ohm load) proportional to a current flowing through the probe inner diameter based on a characteristic impedance of the probe. This can be referred to as the transfer impedance of the probe. This transfer impedance is related to the insertion loss of the probe versus frequency, IL=20*log₁₀(R)−Z_{T}, where IL=insertion loss (dB), R=impedance of the RF circuit=50 ohms, and Z_{T}=transfer impedance (dB ohms).

For the illustrative example shown in FIG. 2A, and probes having similar materials and construction, insertion loss values are in the −40 to −80 dB range for 60 Hz signals, while in the MHz frequency range, such values are typically −10 dB or better. As mentioned above, this behavior provides frequency-selective behavior where RF signals can be injected or detected on live conductors to perform reflectometric measurements without requiring de-energizing the live conductors.

In general, a probe 220 configuration as shown in FIG. 2A is used in other applications for injection of RF signals or detection of RF signals for the purpose of electromagnetic interference immunity or emission testing, where such a probe 220 configuration can sense stray signals that have coupled onto lines, or to induce electromagnetic interference (EMI) onto a line to determine the sensitivity of a system to external EMI, which are both very different use cases than the present reflectometric measurement scheme.

Experimental evaluation of a clamshell inductive current probe having the configuration of the probe 220 shown in FIG. 2A revealed a response sensitivity to cable positioning when under test. In general, off-axis or radial positioning variations of the cable under test can lead to measurement variations that can negatively impact test results. To address such challenges, dielectric spacers were developed and employed. The spacers can take on different configurations and can be used to center and if needed, immobilize the cable under inspection within the opening 224 of the coupler or test probe 220. FIG. 2B-1 and FIG. 2B-2 illustrate generally an example showing a coupler and spacer combination comprising an inductive current probe 220 that is fitted with a two-part dielectric spacer assembly having an outer diameter or configuration configured to fit within opening 224 and having an inner or test diameter 224-B, TD, that is sized to position (e.g., center) a cable under test within an opening defined by the inductive current probe where TD is less than an effective diameter of the opening 224.

Alternatively, or additionally, the dielectric spacer can include external spacer portions 232-CL and 232-CU that nest on one or both sides of the probe 220 with or without an internal centering two-part ring-like spacer. The dielectric spacer portions 232-CL and 232-CU can be sized and shaped to center a cable under inspection so that the cable is held in a consistent position within an opening of the probe 220. For purposes of prototyping or even commercial fabrication, the dielectric spacer portions 232-CL and 232-CU and centering ring elements 234-BL and 234-BU could be additively manufactured (e.g., three dimensionally printed). Such a manufacturing approach is merely illustrative and other approaches such as injection molding or machining or combinations thereof may be used. The spacer portions 232-CL and 232-CU can include a curved inside radius to mate with an outer diameter of a conductor to be inspected. The spacer portions 232-CL and 232-CU are split to allow rotational or translational opening or separation to occur (e.g., like that of the coupler itself) to allow the assembly to be slipped over a cable without requiring the cable to be disconnected. FIG. 2C-1 illustrates an exploded example comprising an inductive current probe 220 defining an opening 224-C and a dielectric spacer arrangement comprising portions 232-CL and 232-CU, which when assembled, establish a centering ring, hole, or passage having a test diameter. The portions 232-CL and 232-CU can be used to position (e.g., center and, for example, hold captive) a cable under test within the opening 224-C defined by the inductive current probe. In the example of FIG. 2C-1 the spacer is located on one side of the coupler while in FIG. 2C-2 two spacers are provided with one on either side of the coupler. The alignment and mounting of the coupler and the external spacers may occur in a variety of different ways including, for example, use of alignment pins and holes, tapered features, screws, clamps, or the like. In other examples, combinations of internal and external spacers may be used. In still other examples, internal spacers may be used for providing centering while external retention elements provide for internal spacer retention with or without necessarily providing additional centering.

The configurations shown in the open views of FIGS. 2B-1 and 2B-2 and in the exploded-views FIG. 2C-1 and FIG. 2C-2 show that a clamshell inductive current probe 220 configuration can be readily positioned over a wire or cable comprising a single conductive structure or multiple conductors, where the clamshell inductive current probe 220 configuration includes or is fitted with a dielectric element or spacer for centering, or otherwise, providing a fixed position of the cable relative to inductive current probe core and any windings relative thereto, such as to reduce noise or improve measurement repeatability. The coupler may be provided with other alignment features or engagement features (e.g., set screws, pins, tabs, or channels), such as for ensuring repeatable and consistent engagement with the coupler. Different spacers may be used depending on a diameter of the opening through the inductive current probe 220 or, for example, based on the diameter of the cable to be tested.

Spacer portions such as 232-CL, 232-CU, 234-BL, and 234-BU may be formed from a compliant material or a rigid material, or combinations thereof. For example, the spacer may include a compliant portion that provides for some amount of self-centering of the cable or to provide for usage with a range of different cable sizes. Generally, portions such as 232-CL, 232-CU, 234-BL, and 234-BU can be formed from a dielectric material having a relative magnetic permeability close to unity to avoid disrupting injection or detection behavior of the probe 220. The dielectric may be formed from a solid material or from a material having void regions to lower a relative permittivity to near unity (e.g., a hollow 3D printed structure). The inductive current probe 220 may be shielded, such as including a conductive sheet or cladding, such as adjacent to the regions where the cable enters and exist the probe 220. As an illustrative example, the dielectric spacer configurations shown in FIG. 2B-1, FIG. 2B-2, and FIG. 2C-1, and FIG. 2C-2 can, as illustrative but non-limiting examples, provide a tolerance of positioning of the cable within the opening of the probe 220 within 5 mm of center, within 3 mm of center, or within 1 mm of center, or some other tolerance.

FIG. 2D illustrates generally an example comprising a test setup, such as where an inductive current probe 220 and a dielectric spacer arrangement (e.g., including portions 232D) are used to position (e.g., center) and hold captive a cable 210 under test within an opening defined by the inductive current probe 220. The illustration of FIG. 2D shows a configuration that was used for experimental evaluation, where a portion of a jacket 248 was stripped from the cable 210. According to the present subject matter, shielded or unshielded cable can be inspected using the inductive coupling technique, though for evaluation of flaws along a single conductor, a shielded portion 246 of the cable 210 may need to be stripped back to provide a region where the inductive current probe 220 can encircle a single conductor 240. An inner dielectric 244 (e.g., insulation between a shielded portion 246 and inner conductor 240) need not be stripped back. An end termination 242 can but need not be disconnected from a source or load device.

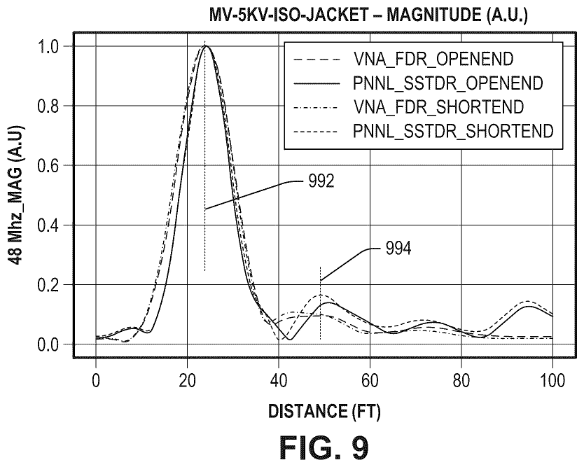

As shown and further described below in relation to FIG. 9, if the inductive current probe 220 encircles a shielded portion 246 of the cable 210, measurements may still be performed, but flaw indications may correspond to different, but nonetheless still useful physical features, such as insulation degradation or shield damage. Similarly, if multiple conductors are located within the opening of the inductive current probe 220, a fault indication may generically indicate the presence of insulation degradation or a conductor fault, but further measurement or physical inspection may be required to determine which conductor or conductors are damaged because the injected excitation signal and reflected signal are coupled to multiple conductors or the outermost conductor (e.g., a shield) in a coaxial configuration.

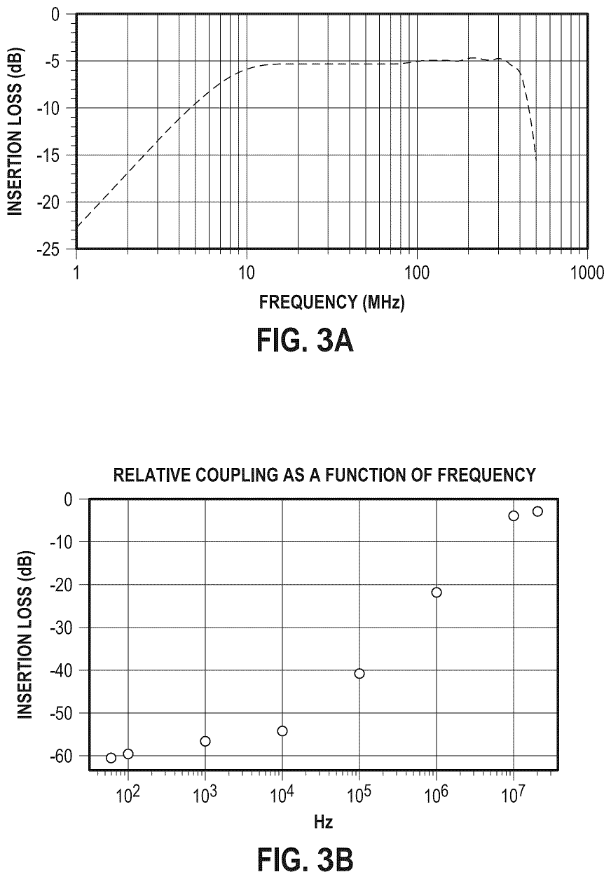

FIG. 3A shows an illustrative example of insertion loss versus frequency from vendor-provided data, for a representative inductive current probe (ICP-622 injection current probe mentioned above) that can be used for inductive coupling of an excitation signal to a cable under test, or for detection of a received signal elicited by such excitation. FIG. 3B shows an illustrative example comprising experimentally obtained insertion loss values measured versus frequency, showing rejection of power line frequencies and lower order harmonics for the same probe as is shown in FIG. 3A.

An ability of a representative inductive current probe to perform high-frequency reflectometry and isolate high-voltage 60 Hz-to-DC signals in the configuration shown was verified. A waveform generator was used to create sine waves from 60 Hz to 80 MHz and the measured peak-to-peak voltage was compared for each frequency sample between a reference “through” path and an output of the inductive current probe.

A ratio of the measured voltages, 20*log₁₀ (V_{coupled}/V_{through}), is shown in FIG. 3B. As expected, the response shows significant suppression at 60 Hz, and there is minimal loss at frequencies greater than 10 MHz. This pattern is similar to the high-pass behavior shown in the insertion loss plot of FIG. 3A. A voltage isolation ability of the inductive current probe was experimentally confirmed on a medium-voltage cable rated to 5 kV using a loss tangent (“Tan Delta”) test instrument to inject a 5 kV, 0.1 Hz signal.

As mentioned above, conductively coupled frequency domain reflectometry (FDR) is being used in nuclear plants, particularly to locate areas of concern on de-energized cables. An FDR instrument, such as implemented using a vector network analyzer (VNA), can be used to directly excite and measure signals by conductively connecting a measurement port of the instrument to a conductor under test and a reference node (e.g., “ground”). This connection type can be referred to as a “tee” configuration.

FIG. 4 illustrates generally an example comprising an instrument architecture for a frequency domain reflectometer (FDR) instrument 450, such as can be included or used with other examples. The FDR instrument 450 can include a swept frequency signal generator 452 to generate a chirped excitation signal, T, which can be inductively coupled using an inductive current probe 420 (e.g., a clamp on coupler like 220) to inject the chirped excitation signal into a cable 410 under inspection. The instrument 450 can receive a signal, R, indicative of a reflection from an impedance discontinuity along the cable length or associated with a parallel conductor within a cable bundle, such as by using a tunable receiver 468 (e.g., a superheterodyne or other frequency-selective receiver architecture). Generally, an inductive current probe 420 includes only a single port (e.g., a coaxial port), so a directional coupler, multiplexer, transmit/receive switch 408, or the like can be used to couple the excitation signal to the inductive current probe 420 and direct any detected reflections to the tunable receiver 468.

By detecting reflections in the frequency domain, noise susceptible frequencies can be rejected. The instrument 450 can then apply an inverse frequency domain transform at 464 (e.g., an inverse Fourier transform such as an inverse Fast Fourier Transform if performed in the digital domain). An output of the inverse transform at 464 can be similar to other time-domain reflectometry techniques, which may be processed to provide magnitude values versus time or versus distance.

A resulting output of magnitude vs. time may be converted to magnitude vs. distance using a velocity of propagation (e.g., a group velocity), if known or measured. A bandwidth for FDR is generally adjustable, such as software configurable if digital synthesis or control is used. Without being bound to these values for all applications, experiment observations indicate that useful responses occur from about 50 MHz to about 500 MHz. Higher-bandwidth FDR chirps produce sharper peaks capable of spatially resolving more closely spaced impedance changes, but higher frequencies do not propagate as far along the cable length before becoming attenuated. Testing can be performed using multiple different bandwidths providing the user with both high- and low-frequency information to consider in evaluating a cable under test.

FIG. 5 illustrates generally an example comprising an instrument architecture for a spread-spectrum time domain reflectometer (SSTDR) instrument 550, which may be included or used with other examples. Spread spectrum time domain reflectometry (SSTDR) can be used to produce measurements similar to time-domain reflectometry or frequency domain reflectometry (FDR). Unlike FDR, detection and processing are generally performed in the time domain. As an illustration, a spreading code can be generated at 554, such as pseudo-random noise (PN) code that is provided to a mixer or modulator 556. A square wave or other baseband signal can be generated by a signal generator 552, which is then modulated by or mixed with the PN code to provide a pseudo-noise modulated excitation signal, T, that is then coupled to a cable 510 under inspection, such as by using an inductive current probe 520. For direct-coupled (e.g., tee-connected) injection not using a current probe 520, a high-pass filter or other coupling circuit 560 can be used. For inductively-coupled applications, as mentioned above, the coupling circuit 560 can include a T/R switch, or directional coupler, or the like.

The instrument 550 can detect a response, R, such as associated with cable anomalies. The SSTDR instrument 550 performs a correlation operation at 558 between the transmitted and received signals (or comparing the input PN code to the detected signal). The correlation-based approach produces a robust noise-tolerant signal response similar to TDR or FDR. The definition of “bandwidth” in the context of FDR is different from that of SSTDR, but generalizations about lower vs. higher bandwidth still apply. SSTDR can be implemented using an arbitrary waveform generator to create spread spectrum waveforms and a digitizing oscilloscope (or other analog-to-digital conversion circuitry) to capture the reference and return signals. The correlation operation at 558 can be implemented in the digital domain. In a laboratory setting, this SSTDR approach was capable of providing a bandwidth up to 500 MHz, although experimental evaluation showed noise for bandwidths above 200 MHz on 100-ft (30.48-meter) cables.

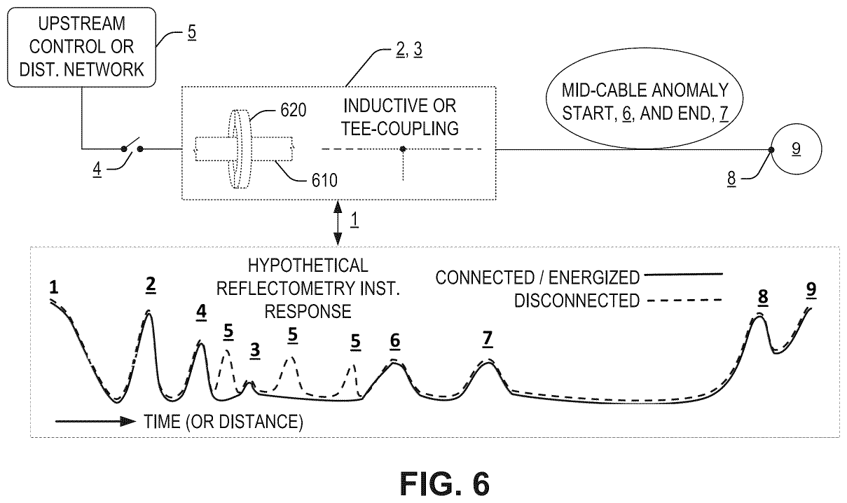

FIG. 6 illustrates generally an example comprising a test configuration showing differences between hypothetical reflectometry measurements for connected (e.g., energized) and disconnected cable configurations, for inductively-coupled and conductively coupled measurements. The test configuration of FIG. 6 shows an arrangement that can be used for conductive (e.g., “tee” connected) or inductively-coupled evaluation of a cable under inspection. The clamshell inductive current probe 620 was experimentally evaluated on a range of damaged and undamaged cables in both the energized and unenergized condition. The test setup shown schematically in FIG. 6 included an approximately 20-ft (6.1-meter) leader cable (represented schematically in FIG. 6 at 1). Reflectometry sends chirped excitation and receives reflection signals equally in both directions along a cable 610 under inspection because the cable 610 behaves like an electrically-long transmission line structure. Closing an energizing switch 4 exposes the reflectometry data to an upstream control or distribution network 5, including branches, tees, splices, or other physical features that can generate their own corresponding reflections and appear on the reflectometry response plot. Such upstream features may not be readily distinguishable from anomalies in the cable 610 under test. Experimental observations shown herein were performed on a cable/motor test bed which supported 480 volts alternating current (VAC). Three-phase energized and unenergized tests were performed using low-voltage EPR (ethylene propylene rubber) cables as described in TABLE 1, below.

TABLE 1
Illustrative examples of low-voltage cable evaluated herein.

| Manufacturer | Insulation | Jacket | Shield |
|---|---|---|---|
| General Cable | EPR | CPE | Yes |

Manufacturer designation: 6-903-SH 14AWG-3/C FR-EP 600 V
FR-EPR/CPE Foil Shielded 600 V E-2

| | | | |
|---|---|---|---|
| General Cable | EPR | CPE | No |

Manufacturer designation: 6-903-G 14AWG-3/C FR-EP 600 V
FR-EPR/CPE Non-Shielded 600 V E-2

The experimental observations were obtained using FDR and SSTDR instruments connected directly (e.g., conductively through tee-connection) to the unenergized cable, instruments connected non-conductively through a clamp-on inductive coupler to an unenergized cable, and instruments connected through a clamshell inductive current probe to a 480 VAC energized cable 610 running a one-half horsepower three-phase motor 9. The cable 610 under inspection included an engineered anomaly (starting at location 6 and ending at location 7), along with an interconnection 8 to the motor 9. In general, a hypothetical reflectometry response is shown for the connected and disconnected examples, showing how closure of the switch 4 creates additional indicia on the response versus the disconnected example. In the connected example, the cable 610 is energized. In general, cable responses when interrogated inductively using a clamp-on probe were similar for both the energized and unenergized case, for both FDR and SSTDR tests.

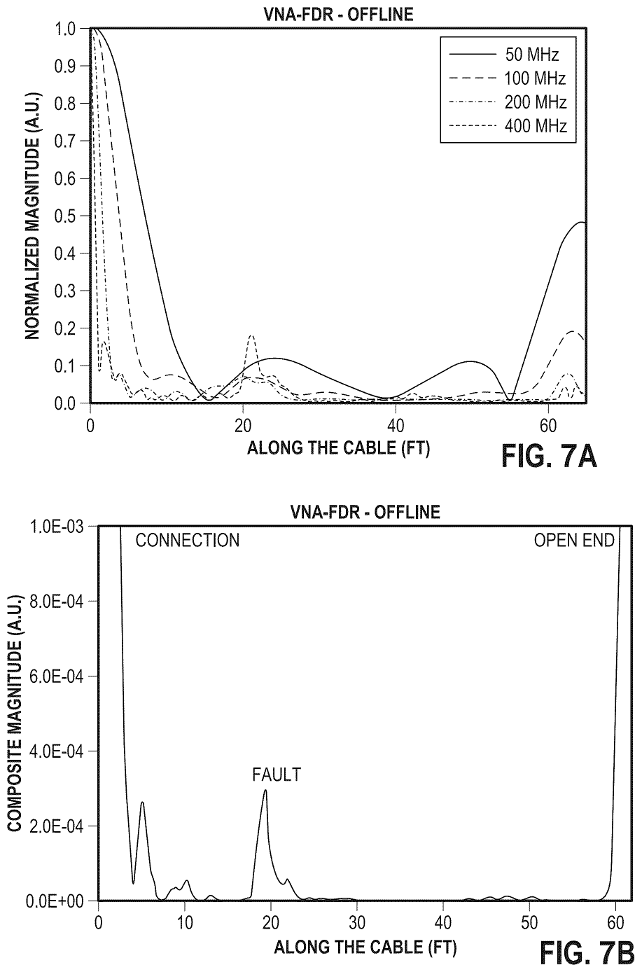

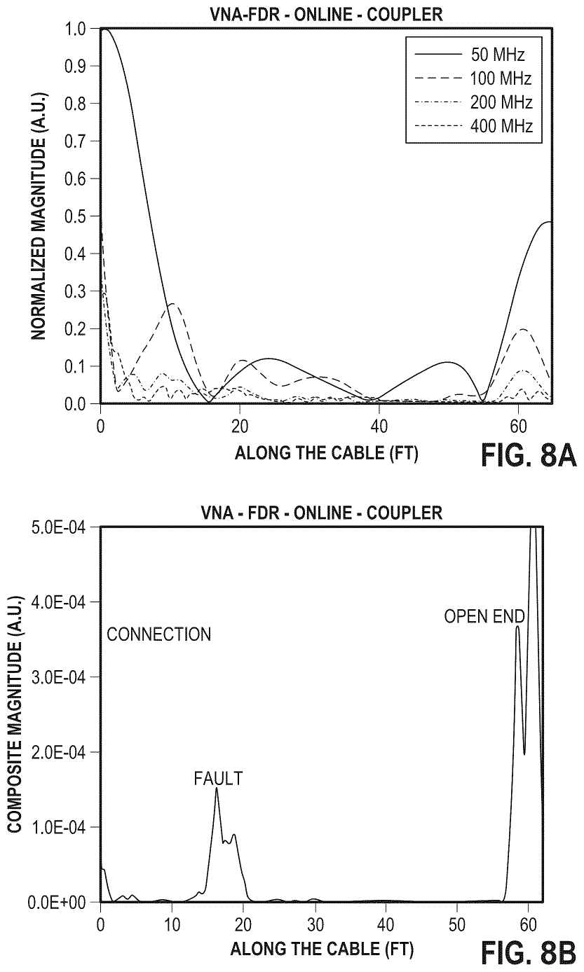

FIG. 7A shows an illustrative example comprising experimentally-obtained normalized magnitude values obtained using a frequency domain reflectometry (FDR) approach using a direct connection and de-energized cable under test, and FIG. 7B shows a composite fault profile after baseline removal and aggregation (e.g., multiplication) of the signals in FIG. 7A to combine them into a composite fault profile. FIG. 8A shows an illustrative example comprising experimentally-obtained normalized magnitude values obtained using a frequency domain reflectometry (FDR) approach using an inductively-coupled connection and 480 VAC energized cable under test, and FIG. 8B shows a composite fault profile after baseline removal and aggregation (e.g., multiplication) of the signals in FIG. 8A to combine them into a composite fault profile.

The FDR magnitude raw data (square root sum of squares [SRSS] of real and imaginary parts) for bandwidths of 50, 100, 200, and 400 MHz are shown in FIG. 7A and FIG. 8A, respectively. An anomaly peak is present but would be difficult to identify from the raw data due to other indications in the magnitude profile. Also, the energized signal of FIG. 8A is similar but not identical to the unenergized plot of FIG. 7A.

Various signal processing approaches can be used. For example, a relatively clear anomaly indication (e.g., a peak) can be elicited using the signal processing strategy outlined below in TABLE 2. A contribution from the leader is first subtracted to focus on the cable under test. Time or distance samples on the plot can be normalized (e.g., padded or interpolated) to establish a specified number of reflectometry samples corresponding to the full cable length. The baseline can be subtracted, if acquired previously. If no baseline data is available, a simulated baseline, or the first measurement available where the cable is assumed to be good may be used. Complex-valued data points can be reduced to magnitude values, such as by using an SRSS determination. Such magnitude values can also be normalized to provide a unitless plot (in “arbitrary units”). Multiple bandwidths may be considered individually or aggregated to form a composite. One way to consider multiple bandwidths contemporaneously is to aggregate the plots for different bandwidths by multiplying their values point wise (e.g., if complex-valued, performing vector multiplication).

TABLE 2
Illustrative Example of Signal Processing Workflow

(1) Eliminate leader
(2) Normalize count of time or distance samples
(3) Subtract baseline
(4) Determine SRSS magnitudes
(5) Aggregate different-bandwidth acquisitions

In general, data interpretation and identification of reflectometry peaks within the raw data from a tested cable can present various challenges. Indicia of anomaly reflections may seem to be present within acquired reflectometric plots corresponding to multiple bandwidth values, but no clear peak may rise above the background noise level using the raw data for any one plot. Using a processing approach as mentioned above may result in a distinguishable peak associated with an anomaly of interest as shown in FIG. 7B and FIG. 8B, respectively. The use of a clamshell inductive current probe provides reflectometric plots that appear quite similar to responses acquired using direct coupling.

The clamshell inductive current probe can provide operational advantages, including both injecting and receiving signals without requiring direct contact with cable conductors being inspected. Experimental evaluation herein demonstrated performance to 5 kV isolation, but the coupler construction shown herein may effectively isolate the test instruments from significantly higher voltage systems into the range of 15 kV or more.

FIG. 9 shows an illustrative example comprising experimentally-obtained normalized magnitude values obtained using a frequency domain reflectometry (FDR) approach using an inductively-coupled clamp-on probe to interrogate a section of medium voltage shielded cable. As mentioned above, if an inductive current probe is installed over a shield, an injected FDR chirp or SSTDR excitation may only be propagated along the shield. Applying the coupler for reflectometry monitoring of a particular conductor may involve cutting a shield back to support installing the clamshell inductive current probe over the insulation of the single conductor as shown in FIG. 2D, above.

If the inductive current probe is clamped over the shield, energy from a high frequency chirp is primarily (or even entirely) injected onto the shield and any shield fault or jacket fault will produce a reflection similar to the fault detection on an interior conductor or the insulation. For the evaluation shown in FIG. 9, the inductive current probe was clamped onto a medium-voltage shielded cable and an FDR response was acquired. Indications associated with the cable ends are clearly visible in FIG. 9. For example, at 992, peaks in the plot for different cases show where a cable starts and, for example, at 994, where the cable ends. Any shield damage would be expected to appear as a similar but earlier reflection from the cable end reflection in a manner similar to reflectometry performed to evaluate an interior conductor or insulation.

FIG. 10A illustrates generally a technique 1000, such as a machine-implemented method that can include or use an inductive coupling approach for performing a reflectometric measurement. At 1002, an excitation signal is generated for inductive application to a conductive structure of a cable. This can include generating a swept-frequency (e.g., chirped) excitation signal or a spread-spectrum time-domain excitation signal, as can be provided by the instrument architectures in FIG. 4 or FIG. 5, where a test instrument such as a frequency domain reflectometer (FDR) or spread-spectrum time domain reflectometer (SSTDR) provides the excitation. The excitation signal is applied to the cable via an inductive current probe, such as the clamp-on probe illustrated in the examples of FIG. 2A through FIG. 2D, enabling non-conductive signal injection onto the cable under test. At 1004, a returned reflected signal can be received inductively from the conductive structure of the cable.

The reflected signal can be obtained using the same or a different inductive current probe, for determination of an indicium of a feature along the cable in resulting reflectometric data (e.g., a local peak in reflected signal magnitude versus time or versus distance). Such features, corresponding to impedance discontinuities, may be indicative of insulation degradation, or conductor faults, as illustrated in the illustrative examples of reflectometric data shown in FIG. 6, FIG. 7A, FIG. 7B, FIG. 8A, FIG. 8B, or FIG. 9. The received signal may be processed to extract magnitude, time, or distance information corresponding to physical loci along the cable.

FIG. 10B illustrates generally another technique 1000B, such as a machine-implemented method that can include or use an inductive coupling approach for performing a reflectometric measurement. In particular, FIG. 10B shows a technique 1000B that can use multiple inductive couplers (two in this illustrative example). The technique 1000B of FIG. 10B includes, at 1002B, an excitation technique similar to 1002 of FIG. 10A, but where excitation signals are generated for transmission by different couplers. At 1006, a first reflected signal comprising a first indicium of a feature is received using a first coupler, such as in response to an inductive-coupled excitation signal transmitted by the first coupler. At 1006, a second reflected signal comprising a second indicium of a feature is received using a second coupler such as in response to an inductive-coupled excitation signal transmitted by the second coupler.

This arrangement is further illustrated below in relation to FIG. 11A through FIG. 11E, where two or more inductive current probes can be positioned at different locations along a cable. Each probe can be used to inject or receive signals, enabling acquisition of reflectometric data from multiple points along the cable. The use of multiple probes allows for comparison and correlation of reflected signals to improve feature localization and reduce ambiguity in determining an origin of detected reflections. Next, at block 1008, a spatial locus of a feature is identified by determining a first candidate locus based on the first time index and corroborating the determination by determining a second candidate locus based on the second time index. The time indices correspond to the timing of reflected signals received at respective probes, and a known nominal or measured separation between probes enables determination of a physical location of a detected feature along the cable. This approach allows for precise localization of anomalies, as described in the context of FIG. 11A through FIG. 11E and supports both energized and de-energized cable monitoring without requiring direct electrical contact with the cable conductors. A portion or an entirety of the technique illustrated in FIGS. 10A and 10B can be implemented using the system architectures and probe configurations shown in FIG. 1, FIG. 2A through FIG. 2D, FIG. 4, and FIG. 5, and is applicable to a range of cable types and operational conditions as described elsewhere herein.

FIG. 11A, FIG. 11B, FIG. 11C, FIG. 11D, and FIG. 11E illustrate generally operations that can include or use two or more inductive coupling probes to perform a reflectometric technique, such as a machine-implemented method. Generally, in reflectometry, excitation signals such as chirps propagate equally in both directions along the cable from the point of injection. If a coupler is installed near a cable end, the excitation can elicit both a signal propagating along the cable section under test in a desired direction, and a signal propagating toward a nearby cable end. Accordingly, the reflected signal may include a contribution from the nearby cable end. If the coupler is positioned well away from a cable end, the excitation propagates in both directions, and reflections may originate from features along the cable, located on either side of the probe. As mentioned above, reflected signal peaks may correspond to features within the cable under test or to impedance changes in connected equipment, such as a motor controller or actuator switch. In some cases, reflections from upstream or downstream components may be mitigated by baseline subtraction, provided the same signals are present in the baseline measurement.

The use of clamshell inductive current probes enables placement of two or more interrogation devices (e.g., inductive couplers) at arbitrary locations along the cable, not limited to the cable ends, and without requiring modification of the cable under test. This configuration provides two potential benefits over single-node testing. First, if the distance between two test nodes is known, a velocity of propagation can be precisely determined by measuring the time for a pulse to travel from one node to another. This enables accurate determination of both the full cable length and the distance to a fault. Second, when excitation waveforms are projected equally in both directions from each test node, any detected reflection can originate from either direction along the cable. For a single node, a reflection at a given time delay could correspond to a feature at either +X or −X distance from the probe, resulting in ambiguity. By comparing and correlating responses from two nodes, it becomes possible to confirm the true location of a feature: if a reflection appears at the same location from both nodes, a flaw location can be corroborated; if a reflection is only observed from one node, the suspected location can be discounted.

FIG. 11A shows a schematic representation of a cable with two couplers or probes (e.g., signal sources and sensors (referred to as “couplers” #1 and #2) positioned at a known, measured, or ascertainable separation, “S,” along the cable. Faults A, B, and C are distributed at different locations. The ability to place couplers 820A and 820B in different (e.g., arbitrary) locations enables sensitivity to features throughout the cable, regardless of coupler proximity to the cable ends. At FIG. 11B, indications associated with possible fault locations as detected from coupler #1 are shown. When a reflectometric excitation is launched from coupler #1, reflections are observed at time intervals corresponding to the distances to faults A, B, and C. Due to bidirectional propagation, each reflection could correspond to a feature located either in the positive or negative direction from the coupler, resulting in ambiguity in the physical location of the detected feature.

FIG. 11C illustrates the possible fault locations as detected from coupler #2. Similarly, reflections are observed at time intervals corresponding to the distances to faults A, B, and C, but the ambiguity remains as to whether the reflection originates to the left or right of the coupler. FIG. 11D demonstrates a process for correlating the responses from both sources. By comparing the reflected signal profiles from both probes, features that are corroborated by both measurement locations can be identified. If a reflection is detected at the same location by both probes, the feature can be localized along the cable with reasonable confidence. If a reflection is only observed from a given location by one probe and not the other, the suspected location can be discounted as a true fault unless separation distance between the couplers is a significant factor in which case a third or additional coupler or coupler location may be used.

FIG. 11E presents a combined time-base analysis, where the fault possibilities from both sources are overlaid. Reflections detected at both sources and at consistent locations are accepted as true fault indications (e.g., AA, BB, CC). Reflections not corroborated between the two sources, or that differ in profile, can be rejected as likely spurious or originating from outside the region of interest. This approach enables precise localization and confirmation of cable anomalies, reducing ambiguity inherent in single-probe reflectometry. The use of two or more inductive current probes, as illustrated in FIG. 11A through FIG. 11E, also allows for determining a velocity of propagation by measuring a time-of-flight between probes at a known separation (or vice versa) and supports accurate distance-to-fault calculations. This technique is applicable to both energized and de-energized cables and does not require modification of the cable under test. The methodology is compatible with the system architectures and probe configurations shown in FIG. 1, FIG. 2A through FIG. 2D, and supports the feature localization and fault discrimination described elsewhere herein.

FIG. 12 illustrates a block diagram of an example comprising a machine 1200 upon which any one or more of the techniques (e.g., methodologies) discussed herein may be performed. Machine 1200 (e.g., computer system) may include a hardware processor 1202 (e.g., a central processing unit (CPU), a graphics processing unit (GPU), a hardware processor core, or any combination thereof), a main memory 1204 and a static memory 1206, connected via an interlink 1230 (e.g., link or bus), as some or all of these components may constitute hardware for systems or related implementations discussed above.

Generally, the hardware processor 1202 may, for example, include at least one of a Central Processing Unit (CPU), a Reduced Instruction Set Computing (RISC) Processor, a Complex Instruction Set Computing (CISC) Processor, a Graphics Processing Unit (GPU), a Digital Signal Processor (DSP), a Tensor Processing Unit (TPU), a Neural Processing Unit (NPU), a Vision Processing Unit (VPU), a Machine Learning Accelerator, an Artificial Intelligence Accelerator, an Application Specific Integrated Circuit (ASIC), a Field Programmable Gate Array (FPGA), a Radio-Frequency Integrated Circuit (RFIC), a Neuromorphic Processor, a Quantum Processor, or any combination thereof. A processor circuit may further be a multi-core processor having two or more independent processors (sometimes referred to as “cores”) that may execute instructions contemporaneously. Multi-core processors contain multiple computational cores on a single integrated circuit die, each of which can independently execute program instructions in parallel. Parallel processing on multi-core processors may be implemented via architectures like superscalar, VLIW, vector processing, or SIMD that allow each core to run separate instruction streams concurrently. A processor circuit may be emulated in software, running on a physical processor, as a virtual processor or virtual circuit. The virtual processor may behave like an independent processor but is implemented in software rather than hardware.

Specific examples of main memory 1204 include Random Access Memory (RAM), and semiconductor memory devices, which may include storage locations in semiconductors such as registers. Specific examples of static memory 1206 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; or optical media such as CD-ROM and DVD-ROM disks.

The machine 1200 may further include a display device 1210, an input device 1212 (e.g., a keyboard), and a user interface (UI) navigation device 1214 (e.g., a mouse). In an example, the display device 1210, input device 1212, and UI navigation device 1214 may be a touch-screen display. The machine 1200 may include a mass storage device 1208 (e.g., drive unit), a signal generation device 1218 (e.g., a speaker), a network interface device 1220, and one or more sensors 1216, such as a global positioning system (GPS) sensor, compass, accelerometer, or some other sensor. The machine 1200 may include an output controller 1228, such as a serial (e.g., universal serial bus (USB), parallel, or other wired or wireless (e.g., infrared (IR), near field communication (NFC), etc.) connection to communicate with or control one or more peripheral devices (e.g., a printer, card reader, etc.).

The mass storage device 1208 may comprise a machine-readable medium 1222 on which is stored one or more sets of data structures or instructions 1224 (e.g., software) embodying or utilized by any one or more of the techniques or functions described herein. The instructions 1224 may also reside, completely or at least partially, within the main memory 1204, within static memory 1206, or within the hardware processor 1202 during execution thereof by the machine 1200. In an example, one or any combination of the hardware processor 1202, the main memory 1204, the static memory 1206, or the mass storage device 1208 comprises a machine readable medium.

Specific examples of machine-readable media include, one or more of non-volatile memory, such as semiconductor memory devices (e.g., EPROM or EEPROM) and flash memory devices; magnetic disks, such as internal hard disks and removable disks; magneto-optical disks; RAM; or optical media such as CD-ROM and DVD-ROM disks. While the machine-readable medium is illustrated as a single medium, the term “machine readable medium” may include a single medium or multiple media (e.g., a centralized or distributed database, or associated caches and servers) configured to store the one or more instructions 1224.

An apparatus of the machine 1200 includes one or more of a hardware processor 1202 (e.g., a central processing unit (CPU), a graphics processing unit (GPU), a hardware processor core, or any combination thereof), a main memory 1204 and a static memory 1206, sensors 1216, network interface device 1220, antennas, a display device 1210, an input device 1212, a UI navigation device 1214, a mass storage device 1208, instructions 1224, a signal generation device 1218, or an output controller 1228. The apparatus may be configured to perform one or more of the methods or operations disclosed herein.

The term “machine readable medium” includes, for example, any medium that is capable of storing, encoding, or carrying instructions for execution by the machine 1200 and that cause the machine 1200 to perform any one or more of the techniques of the present disclosure or causes another apparatus or system to perform any one or more of the techniques, or that is capable of storing, encoding or carrying data structures used by or associated with such instructions. Non-limiting machine-readable medium examples include solid-state memories, optical media, or magnetic media. Specific examples of machine-readable media include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); or optical media such as CD-ROM and DVD-ROM disks. In some examples, machine readable media includes non-transitory machine-readable media. In some examples, machine readable media includes machine readable media that is not a transitory propagating signal.

The instructions 1224 may be transmitted or received, for example, over a communications network 1226 using a transmission medium via the network interface device 1220 utilizing any one of a number of transfer protocols (e.g., frame relay, internet protocol (IP), transmission control protocol (TCP), user datagram protocol (UDP), hypertext transfer protocol (HTTP), etc.). Example communication networks include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®), IEEE 802.15.4 family of standards, a Long Term Evolution (LTE) 4G or 5G family of standards, a Universal Mobile Telecommunications System (UMTS) family of standards, peer-to-peer (P2P) networks, satellite communication networks, among others.

In an example, the network interface device 1220 includes one or more physical jacks (e.g., Ethernet, coaxial, or other interconnection) or one or more antennas to access the communications network 1226. In an example, the network interface device 1220 includes one or more antennas to wirelessly communicate using at least one of single-input multiple-output (SIMO), multiple-input multiple-output (MIMO), or multiple-input single-output (MISO) techniques. In some examples, the network interface device 1220 wirelessly communicates using Multiple User MIMO techniques. The term “transmission medium” shall be taken to include any intangible medium that is capable of storing, encoding or carrying instructions for execution by the machine 1200, and includes digital or analog communications signals or other intangible medium to facilitate communication of such software.

### Various Notes

Example 1 comprises a system for reflectometric evaluation of a cable, the system comprising an excitation circuit configured to generate an excitation signal for inductive application to a conductive structure of a cable for spread-spectrum time domain reflectometry (SSTDR) or frequency domain reflectometry (FDR), a measurement circuit configured to receive a reflected signal obtained inductively from the conductive structure of the cable, the reflected signal for use in determining an indicium of a feature along the cable using the spread-spectrum time domain reflectometry (SSTDR) or the frequency domain reflectometry (FDR), and at least one inductive current probe defining an opening to encircle an outer diameter of the cable, the inductive current probe configured to at least one of inductively apply the excitation signal or inductively receive the reflected signal, or both inductively applying the excitation signal and inductively receiving the reflected signal.

In Example 2, the system of Example 1 optionally includes that the at least one inductive current probe comprises a clamp-on configuration defining an opened configuration and a closed configuration, the open configuration allowing the inductive current probe to be applied to or removed from the cable.

In Example 3, the system of any of Examples 1 or 2 optionally includes that the at least one inductive current probe comprises a dielectric spacer located on or within an opening of the inductive current probe, the dielectric spacer sized and shaped to center the cable within the opening.

In Example 4, the system of Example 3 optionally includes that the dielectric spacer is removable.

In Example 5, the system of any of Examples 1 through 4 optionally includes that the at least one inductive current probe comprises two or more inductive current probes for positioning at different locations along the cable, respectively.

In Example 6, the system of Example 5 optionally includes that a first one of the two or more inductive current probes is configured to inductively apply the excitation signal at a first location along the cable, and that a second one of the two or more inductive current probes is configured to inductively receive the reflected signal at a different second location.

In Example 7, the system of Example 5 optionally includes that a first one of the two or more inductive current probes is configured to obtain a first reflected signal for use in determining a first indicium of the feature corresponding to a first time index, and that a second one of two or more inductive current probes is configured to obtain a second reflected signal for use in determining a second indicium of the feature corresponding to a second time index.

In Example 8, the system of Example 7 optionally includes a control circuit configured to identify a spatial locus of the feature using the first and second indicia.

In Example 9, the system of Example 8 optionally includes that the control circuit is configured to identify the spatial locus of the feature by determining a first candidate locus based on the first time index and corroborating the determination by determining a second candidate locus based on the second time index, using information indicative of a separation between the first one of the two or more inductive current probes and the second one of the two or more inductive current probes.

In Example 10, the system of Example 9 optionally includes that the control circuit is configured to determine the separation between the first one of the two or more inductive current probes and the second one of the two or more inductive current probes using a time-of-flight determination and a propagation velocity.

In Example 11, the system of any of Examples 1 through 10 optionally further comprises the cable.

In Example 12, the system of any of Examples 1 through 11 optionally includes that the cable comprises multiple conductive structures.

In Example 13, the system of any of Examples 1 through 2 optionally includes that the conductive structure comprises a shield conductor.

In Example 14, the system of Example 13 optionally includes that the at least one inductive current probe is configured to encircle a region of the cable without the shield conductor.

In Example 15, the system of any of Examples 1 through 14 optionally includes that the cable is energized during at least one of (1) inductive application of the excitation signal or (2) inductive receiving of the reflected signal.

In Example 16, the system of any of Examples 1 through 15 optionally includes that the feature corresponds to a region along the cable comprising thermal damage, mechanical damage, an insulation defect, or a conductor defect, or combinations thereof.

Example 17 comprises a method for reflectometric evaluation of a cable, the method comprising: generating an excitation signal for inductive application to a conductive structure of a cable for spread-spectrum time domain reflectometry (SSTDR) or frequency domain reflectometry (FDR), in response to the excitation signal, receiving a reflected signal obtained inductively from the conductive structure of the cable, the reflected signal for use in determining an indicium of a feature along the cable using the spread-spectrum time domain reflectometry (SSTDR) or the frequency domain reflectometry (FDR), and that at least one of the inductive application or the receiving the reflected signal is performed, or both are performed, using at least one inductive current probe defining an opening to encircle an outer diameter of the cable.

In Example 18, the method of Example 17 optionally includes that the at least one inductive current probe comprises two or more inductive current probes positioned at different locations along the cable, respectively.

In Example 19, the method of Example 18 optionally includes that a first one of the two or more inductive current probes inductively applies the excitation signal at a first location along the cable; and that a second one of the two or more inductive current probes inductively receives the reflected signal at a different second location.

In Example 20, the method of Example 18 optionally includes that a first one of the two or more inductive current probes receives a first reflected signal comprising a first indicium of the feature corresponding to a first time index, and that a second one of two or more inductive current probes receives a second reflected signal comprising a second indicium of the feature corresponding to a second time index, and that the method comprises identifying a spatial locus of the feature using the first and second indicia.

In Example 21, the method of Example 20 optionally includes that identifying the spatial locus of the feature comprises determining a first candidate locus based on the first time index and corroborating the determination by determining a second candidate locus based on the second time index, using information indicative of a separation between the first one of the two or more inductive current probes and the second one of the two or more inductive current probes.

In Example 22, the method of any one of Examples 17 through 21 optionally includes that the cable is energized during at least one of (1) application of the excitation signal or (2) receiving of the reflected signal.

In Example 23, the method of Example 22 optionally includes that the at least one inductive current probe is configured to encircle a region of the cable without a shield conductor.

In Example 24, the method of any of Examples 17 through 23 optionally includes that the feature corresponds to a region along the cable comprising thermal damage, mechanical damage, an insulation defect, or a conductor defect, or combinations thereof.

Example 25 comprises a machine-readable medium comprising instructions, that, when executed by at least one processor circuit, cause a system for reflectometric evaluation of a cable to perform the method of any of Examples 17 through 24.

Each of the non-limiting examples above can stand on its own or can be combined in various permutations or combinations with one or more of the other aspects or other subject matter described in this document.

The above detailed description includes references to the accompanying drawings, which form a part of the detailed description. The drawings show, by way of illustration, specific embodiments in which the invention can be practiced. These embodiments are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc., are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A system for reflectometric evaluation of a cable, the system comprising:
an excitation circuit configured to generate an excitation signal for inductive application to a conductive structure of a cable for spread-spectrum time domain reflectometry (SSTDR) or frequency domain reflectometry (FDR);
a measurement circuit configured to receive a reflected signal obtained inductively from the conductive structure of the cable, the reflected signal for use in determining an indicium of a feature along the cable using the spread-spectrum time domain reflectometry (SSTDR) or the frequency domain reflectometry (FDR); and
at least one inductive current probe defining an opening to encircle an outer diameter of the cable, the inductive current probe configured to at least one of inductively apply the excitation signal or inductively receive the reflected signal, or both inductively applying the excitation signal and inductively receiving the reflected signal.

2. The system of claim 1, wherein the at least one inductive current probe comprises a clamp-on configuration defining an opened configuration and a closed configuration, the open configuration allowing the inductive current probe to be applied to or removed from the cable.

3. The system of claim 1, wherein the at least one inductive current probe comprises a dielectric spacer located on or within an opening of the inductive current probe, the dielectric spacer sized and shaped to center the cable within the opening.

4. The system of claim 1, wherein the at least one inductive current probe comprises two or more inductive current probes for positioning at different locations along the cable, respectively.

5. The system of claim 4, wherein a first one of the two or more inductive current probes is configured to inductively apply the excitation signal at a first location along the cable; and
wherein a second one of the two or more inductive current probes is configured to inductively receive the reflected signal at a different second location.

6. The system of claim 4, wherein a first one of the two or more inductive current probes is configured to obtain a first reflected signal for use in determining a first indicium of the feature corresponding to a first time index; and
wherein a second one of two or more inductive current probes is configured to obtain a second reflected signal for use in determining a second indicium of the feature corresponding to a second time index.

7. The system of claim 6, comprising a control circuit configured to identify a spatial locus of the feature using the first and second indicia.

8. The system of claim 7, wherein the control circuit is configured to identify the spatial locus of the feature by determining a first candidate locus based on the first time index and corroborating the determination by determining a second candidate locus based on the second time index, using information indicative of a separation between the first one of the two or more inductive current probes and the second one of the two or more inductive current probes.

9. The system of claim 1, wherein the cable comprises multiple conductive structures.

10. The system of claim 1, wherein the conductive structure comprises a shield conductor.

11. The system of claim 10, wherein the at least one inductive current probe is configured to encircle a region of the cable without the shield conductor.

12. The system of claim 1, wherein the cable is energized during at least one of (1) inductive application of the excitation signal or (2) inductive receiving of the reflected signal.

13. A method for reflectometric evaluation of a cable, the method comprising:
generating an excitation signal for inductive application to a conductive structure of a cable for spread-spectrum time domain reflectometry (SSTDR) or frequency domain reflectometry (FDR);
in response to the excitation signal, receiving a reflected signal obtained inductively from the conductive structure of the cable, the reflected signal for use in determining an indicium of a feature along the cable using the spread-spectrum time domain reflectometry (SSTDR) or the frequency domain reflectometry (FDR); and
wherein at least one of the inductive application or the receiving the reflected signal is performed, or both are performed, using at least one inductive current probe defining an opening to encircle an outer diameter of the cable.

14. The method of claim 13, wherein the at least one inductive current probe comprises two or more inductive current probes positioned at different locations along the cable, respectively.

15. The method of claim 14, wherein a first one of the two or more inductive current probes inductively applies the excitation signal at a first location along the cable; and
wherein a second one of the two or more inductive current probes inductively receives the reflected signal at a different second location.

16. The method of claim 14, wherein a first one of the two or more inductive current probes receives a first reflected signal comprising a first indicium of the feature corresponding to a first time index; and
wherein a second one of two or more inductive current probes receives a second reflected signal comprising a second indicium of the feature corresponding to a second time index; and
wherein the method comprises identifying a spatial locus of the feature using the first and second indicia.

17. The method of claim 16, wherein identifying the spatial locus of the feature comprises determining a first candidate locus based on the first time index and corroborating the determination by determining a second candidate locus based on the second time index, using information indicative of a separation between the first one of the two or more inductive current probes and the second one of the two or more inductive current probes.

18. The method of claim 13, wherein the cable is energized during at least one of (1) application of the excitation signal or (2) receiving of the reflected signal.

19. The method of claim 13, wherein the feature corresponds to a region along the cable comprising thermal damage, mechanical damage, an insulation defect, or a conductor defect, or combinations thereof.

20. A machine-readable medium comprising instructions, that, when executed by at least one processor circuit, cause a system for reflectometric evaluation of a cable to:
generate an excitation signal for inductive application to a conductive structure of a cable for spread-spectrum time domain reflectometry (SSTDR) or frequency domain reflectometry (FDR);
in response to the excitation signal, receive a reflected signal obtained inductively, at a first location, from the conductive structure of the cable, the reflected signal for use in determining a first indicium of a feature along the cable using the spread-spectrum time domain reflectometry (SSTDR) or the frequency domain reflectometry (FDR); and
identify a spatial locus of the feature along the cable including corroborating a candidate spatial locus corresponding to the first indicium using another reflectometric measurement performed at a second location along the cable.
